(19) United States
(12) Patent Application Publication
(10) Pub. No.: US 2025/0287592 A1
(43) Pub. Date: Sep. 11, 2025

(54) SEMICONDUCTOR MEMORY DEVICE

(71) Applicant: Kioxia Corporation, Tokyo (JP)

(72) Inventor: Takehiro NAKAI, Yokkaichi Mie (JP)

(73) Assignee: Kioxia Corporation, Tokyo (JP)

(21) Appl. No.: 18/826,985

(22) Filed: Sep. 6, 2024

(30) Foreign Application Priority Data
Mar. 5, 2024 (JP) 2024-033015

(51) Int. Cl. H10B 43/27; H10B 41/27

(52) U.S. Cl. CPC H10B 43/27; H10B 41/27

(57) ABSTRACT

According to one embodiment, a semiconductor memory device includes: a substrate including a first region and a second region surrounding an outside of the first region; a first member configured to separate a well region provided in the substrate and a region of the substrate provided to surround the well region; a plurality of conductor layers provided above the first region; a memory pillar provided above the first region and extending through the plurality of conductor layers; a plurality of stacked members provided above the second region; and a second member provided between the plurality of stacked members and the first region, wherein a lower surface of the second member is located below a lower surface of the first member.

### CROSS-REFERENCE TO RELATED APPLICATIONS

This application is based upon and claims the benefit of priority from Japanese Patent Application No. 2024-033015, filed Mar. 5, 2024, the entire contents of which are incorporated herein by reference.

### FIELD

Embodiments described herein relate generally to a semiconductor memory device.

### BACKGROUND

As a semiconductor memory device capable of nonvolatilely storing data, a NAND flash memory is known. A semiconductor memory device such as a NAND flash memory employs a three-dimensional memory structure to increase the capacity and the degree of integration.

### BRIEF DESCRIPTION OF THE DRAWINGS

FIG. 1 is a block diagram showing an example of the configuration of a memory system including a semiconductor memory device according to an embodiment.

FIG. 2 is a circuit diagram showing an example of the circuit configuration of a memory cell array provided in the semiconductor memory device according to the embodiment.

FIG. 3 is a plan view showing an example of the planar layout of the semiconductor memory device according to the embodiment.

FIG. 4 is a sectional view showing an example of the sectional structure of the semiconductor memory device according to the embodiment, which is taken along a line IV-IV in FIG. 3.

FIG. 5 is a sectional view showing an example of the sectional structure of the memory pillar of the memory cell array provided in the semiconductor memory device according to the embodiment, which is taken along a line V-V in FIG. 4.

FIG. 6 is a plan view showing an example of the planar layout of the semiconductor memory device according to the first modification.

FIG. 7 is a sectional view showing an example of the sectional structure of the semiconductor memory device according to the second modification.

FIG. 8 is a sectional view showing an example of a defect fixing portion provided in the semiconductor memory device according to the third modification.

### DETAILED DESCRIPTION

In general, according to one embodiment, a semiconductor memory device includes: a substrate including a first region and a second region surrounding an outside of the first region when viewed from above; a first member configured to separate, in a direction parallel to the substrate, a well region provided in the substrate and a region of the substrate provided to surround the well region when viewed from above; a plurality of conductor layers provided above the first region and arranged apart from each other in a first direction perpendicular to the substrate; a memory pillar provided above the first region and extending through the plurality of conductor layers, whose portions crossing the plurality of conductor layers each function as a memory cell; a plurality of stacked members provided above the second region and arranged apart from each other in the first direction; and a second member provided between the plurality of stacked members and the first region in a second direction crossing the first direction, wherein a lower surface of the second member is located below a lower surface of the first member.

Embodiments will be described below with reference to the accompanying drawings. Dimensions and ratios in the drawings do not necessarily match the actuality.

Note that in the following description, the same reference numerals denote constituent elements having almost the same functions and configurations. To particularly discriminate elements having the same configuration, characters or numbers different from each other may be added to the end of the same reference numeral.

### 1. Embodiment

### 1.1 Configuration

### 1.1.1 Memory System

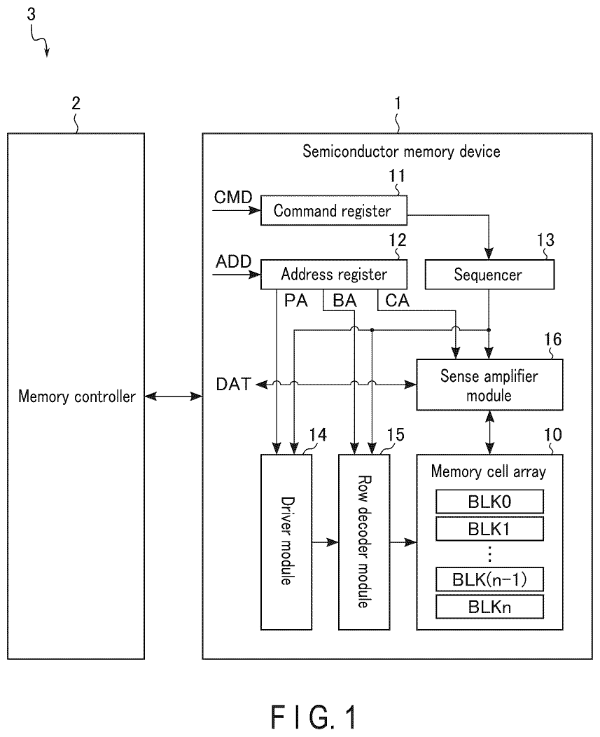

The configuration of a memory system will be described with reference to FIG. 1. FIG. 1 is a block diagram showing an example of the configuration of the memory system including a semiconductor memory device according to the embodiment.

A memory system 3 is, for example, a memory card such as an SD™ card, a UFS (Universal Flash Storage), and an SSD (Solid State Drive). The memory system 3 includes a semiconductor memory device 1 and a memory controller 2. The memory system 3 is configured to be coupled to an external host apparatus (not shown).

The memory controller 2 is formed by, for

example, an integrated circuit such as an SoC (System-on-a-Chip). The memory controller 2 controls the semiconductor memory device 1 based on a request from the host apparatus. For example, the memory controller 2 writes data write-requested by the host apparatus to the semiconductor memory device 1. Furthermore, for example, the memory controller 2 reads out data read-requested by the host apparatus from the semiconductor memory device 1 and transmits it to the host apparatus.

The semiconductor memory device 1 is, for example, a NAND flash memory. The semiconductor memory device 1 nonvolatilely stores data. Communication between the semiconductor memory

device 1 and the memory controller 2 is based on, for example, an SDR (Single Data Rate) interface, a toggle DDR (Double Data Rate) interface, or an ONFI (Open NAND Flash Interface).

### 1.1.2 Semiconductor Memory Device

The internal configuration of the semiconductor memory device 1 will continuously be described with reference to FIG. 1. The semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). Each of the plurality of blocks BLK0 to BLKn will simply be referred to as the block BLK hereinafter when the plurality of blocks BLK0 to BLKn are not discriminated. The block BLK is a set of a plurality of memory cells capable of nonvolatilely storing data. The block BLK is used as, for example, a data erase unit. Furthermore, the memory cell array 10 is provided with a plurality of bit lines and a plurality of word lines. One memory cell is associated with, for example, one bit line and one word line.

The command register 11 stores a command CMD that the semiconductor memory device 1 receives from the memory controller 2. The command CMD includes, for example, an instruction for causing the sequencer 13 to execute a read operation, a write operation, an erase operation, or the like.

The address register 12 stores address information ADD that the semiconductor memory device 1 receives from the memory controller 2. The address information ADD includes, for example, a page address PA, a block address BA, and a column address CA. For example, the page address PA, the block address BA, and the column address CA are used to select a word line, the block BLK, and a bit line, respectively.

The sequencer 13 controls the operation of the entire semiconductor memory device 1. For example, the sequencer 13 controls the operations of the driver module 14, the row decoder module 15, the sense amplifier module 16, and the like based on the command CMD held in the command register 11. Thus, the read operation, the write operation, the erase operation, and the like are executed.

The driver module 14 generates a voltage to be used in the read operation, the write operation, the erase operation, or the like. Based on, for example, the page address PA held in the address register 12, the driver module 14 applies the generated voltage to a signal line corresponding to a selected word line.

Based on the block address BA held in the address register 12, the row decoder module 15 selects one corresponding block BLK in the memory cell array 10. The row decoder module 15 transfers, for example, the voltage applied to the signal line corresponding to the selected word line to the selected word line in the selected block BLK.

In the write operation, the sense amplifier module 16 transfers, to the memory cell array 10, write data DAT received from the memory controller 2. Furthermore, in the read operation, the sense amplifier module 16 determines data stored in a memory cell based on the voltage of a bit line. The sense amplifier module 16 transfers the determination result as the read data DAT to the memory controller 2.

### 1.1.3 Circuit Configuration of Memory Cell Array

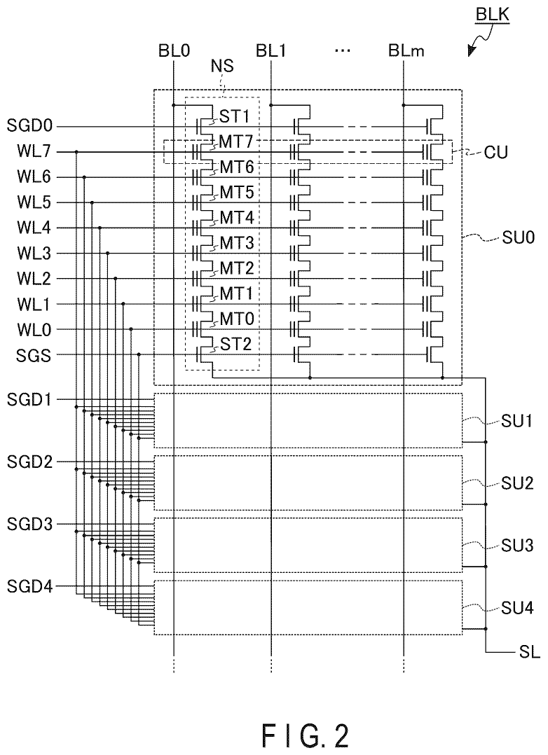

An example of the circuit configuration of the memory cell array 10 will be described with reference to FIG. 2. FIG. 2 is a circuit diagram showing an example of the circuit configuration of the memory cell array provided in the semiconductor memory device according to the embodiment. FIG. 2 shows one block BLK of the plurality of blocks BLK included in the memory cell array 10.

In the memory cell array 10, each block BLK includes, for example, five string units SU0 to SU4. Each of the string units SU0 to SU4 will simply be referred to as the string unit SU hereinafter when the string units SU0 to SU4 are not discriminated. Note that in the example shown in FIG. 2, each block BLK includes the five string units SU, but the present invention is not limited to this. The number of string units SU included in each block BLK may be one to four, or six or more.

Each string unit SU includes a plurality of NAND strings NS associated with bit lines BL0 to BLm (m is an integer of 1 or more), respectively. Each NAND string NS includes, for example, memory cell transistors MT0 to MT7 and selection transistors ST1 and ST2. Each of the memory cell transistors MT0 to MT7 includes a control gate and a charge accumulation film. Each of the memory cell transistors MT0 to MT7 nonvolatilely stores data. Each of the selection transistors ST1 and ST2 is used to select the string unit SU in various kinds of operations. Note that each of the bit lines BL0 to BLm will simply be referred to as the bit line BL hereinafter when the bit lines BL0 to BLm are not discriminated. In addition, each of the memory cell transistors MT0 to MT7 will simply be referred to as the memory cell transistor MT hereinafter when the memory cell transistors MT0 to MT7 are not discriminated.

In each NAND string NS, the memory cell transistors MT0 to MT7 are coupled in series. The first end of the selection transistor ST1 is coupled to the bit line BL associated with the selection transistor ST1. The second end of the selection transistor ST1 is coupled to one end of the serially coupled memory cell transistors MT0 to MT7. The first end of the selection transistor ST2 is coupled to the other end of the serially coupled memory cell transistors MT0 to MT7. The second end of the selection transistor ST2 is coupled to a source line SL.

In the same block BLK, the control gates of the memory cell transistors MT0 to MT7 are coupled to word lines WL0 to WL7, respectively. The gates of the selection transistors ST1 in the string units SU0 to SU4 are coupled to selection gate lines SGD0 to SGD4, respectively. To the contrary, the gates of the plurality of selection transistors ST2 are commonly coupled to a selection gate line SGS. However, the present invention is not limited to this, and the gates of the plurality of selection transistors ST2 may be coupled to a plurality of different selection gate lines for the respective string units SU. Note that each of the word lines WL0 to WL7 will simply be referred to as the word line WL hereinafter when the word lines WL0 to WL7 are not discriminated.

Different column addresses are assigned to the bit lines BL0 to BLm. Each bit line BL is shared by the NAND strings NS to which the same column address is assigned among the plurality of blocks BLK. The word lines WL0 to WL7 are provided for each block BLK. The source line SL is shared by, for example, the plurality of blocks BLK.

A set of the plurality of memory cell transistors MT coupled to the common word line WL in one string unit SU is called, for example, a cell unit CU. For example, the storage capacity of the cell unit CU including the plurality of memory cell transistors MT each of which stores 1-bit data is defined as “1 page data”. The cell unit CU can have a storage capacity of 2 page data or more in accordance with the number of bits of data to be stored in the memory cell transistors MT.

Note that the circuit configuration of the memory cell array 10 is not limited to the above-described configuration. For example, the number of string units SU included in each block BLK can be designed to an arbitrary number. The number of memory cell transistors MT and the number of selection transistors ST1 and ST2 included in each NAND string NS can be designed to arbitrary numbers.

### 1.1.4 Structure of Semiconductor Memory Device

The structure of the semiconductor memory device 1 will be described.

### 1.1.4.1 Planar Layout

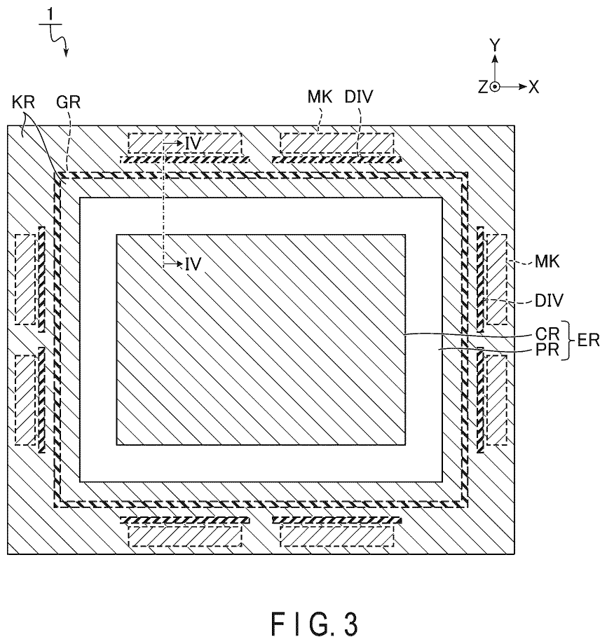

The planar layout of the semiconductor memory device 1 according to the embodiment will be described with reference to FIG. 3. FIG. 3 is a plan view showing an example of the planar layout of the semiconductor memory device according to the embodiment. Note that in the following description and drawings, an X direction corresponds to the extending direction of the word line WL. A Y direction crossing the X direction corresponds to the extending direction of the bit line BL. A Z direction crossing the X direction and the Y direction corresponds to a vertical direction to the surface of a semiconductor substrate of the semiconductor memory device 1. Note that in the semiconductor memory device 1, a side on which the memory cell array 10 out of the semiconductor substrate and the memory cell array 10 is provided is called an upper side hereinafter, and a side on which the semiconductor substrate out of the semiconductor substrate and the memory cell array 10 is provided is called a lower side.

The semiconductor memory device 1 is divided into, for example, an element region ER and a kerf region KR.

The element region ER is a region where elements forming the semiconductor memory device 1, such as the memory cell array 10, the command register 11, the address register 12, the sequencer 13, the driver module 14, the row decoder module 15, and the sense amplifier module 16, are provided.

The element region ER is, for example, a rectangular region. The element region ER is divided into, for example, a core region CR and a peripheral circuit region PR. Note that FIG. 3 shows one core region CR but the number of core regions CR is not limited to one. The number of core regions CR may be two or more.

The core region CR is, for example, a rectangular region provided at the center of the element region ER. The memory cell array 10 is arranged in the core region CR.

Note that the core region CR is not limited to the rectangular shape, and can be arranged in an arbitrary shape and in an arbitrary region in the element region ER.

The peripheral circuit region PR is a region surrounding the outer periphery of the core region CR in the element region ER. In the peripheral circuit region PR, for example, the command register 11, the address register 12, the sequencer 13, the driver module 14, the row decoder module 15, the sense amplifier module 16, and the like are arranged. In addition, in the peripheral circuit region PR, a plurality of external coupling terminals to be used for coupling the semiconductor memory device 1 and an external apparatus are arranged. The semiconductor memory device 1 transmits/receives signals to/from the external apparatus via the external coupling terminal. Furthermore, the semiconductor memory device 1 is externally supplied with power via the external coupling terminal.

The kerf region KR is a region surrounding the outer periphery of the element region ER. The kerf region KR is a region including a chip end portion. In a dicing process, the kerf region is provided by separating a plurality of semiconductor memory devices 1 formed on a wafer. The kerf region KR is provided with, for example, a plurality of alignment marks MK, a plurality of members DIV, a guard ring GR, a characteristic check pattern, and the like to be used in manufacturing of the semiconductor memory device 1. In FIG. 3, a region where the plurality of alignment marks MK, the plurality of members DIV, and the guard ring GR are provided is indicated by dotted lines. FIG. 3 shows an example in which eight alignment marks MK and eight members DIV are provided, but the present invention is not limited to this. The number of alignment marks MK and the number of members DIV are not limited to eight and need only be one or more.

Each alignment mark MK has, for example, a rectangular shape when viewed from above. The sectional structure of the alignment mark MK will be described later.

The plurality of members DIV are provided in correspondence with the plurality of alignment marks MK, respectively. For example, each member DIV is provided to be aligned with the element region ER and the alignment mark MK corresponding to the member DIV in the X direction or the Y direction. The member DIV is, for example, provided between the element region ER and the alignment mark MK in a direction aligned with the element region ER and the alignment mark MK. The member DIV aligned with the alignment mark MK in the X direction is, for example, longer in the Y direction than the alignment mark MK corresponding to the member DIV. More specifically, for example, the member DIV aligned with the alignment mark MK in the X direction is provided from a position closer to one end side than one end of the alignment mark MK in the Y direction to a position closer to the other end side than the other end of the alignment mark MK in the Y direction.

Furthermore, the member DIV aligned with the alignment mark MK in the Y direction is, for example, longer in the X direction than the alignment mark MK corresponding to the member DIV. More specifically, for example, the member DIV aligned with the alignment mark MK in the Y direction is provided from a position closer to one end side than one end of the alignment mark MK in the X direction to a position closer to the other end side than the other end of the alignment mark MK in the X direction. The sectional structure of the member DIV will be described later.

Note that the planar layout of the member DIV is not limited to the above-described one. The member DIV aligned with the alignment mark MK in the X direction may have, for example, a length in the Y direction equal to or shorter than that of the alignment mark MK corresponding to the member DIV. Furthermore, the member DIV aligned with the alignment mark MK in the Y direction may have, for example, a length in the X direction equal to or shorter than that of the alignment mark MK corresponding to the member DIV.

The guard ring GR is, for example, provided to surround the element region ER. For example, the guard ring GR fixes the outer periphery of the semiconductor memory device 1 to the same potential (ground potential VSS) to stabilize the potential of a component such as a well provided in the semiconductor substrate. Furthermore, for example, the guard ring GR suppresses an impurity from entering from silicon exposed in the end portion of the semiconductor memory device 1. The guard ring GR is provided, for example, inside the plurality of members DIV in the semiconductor memory device 1 when viewed from above.

### 1.1.4.2 Sectional Structure

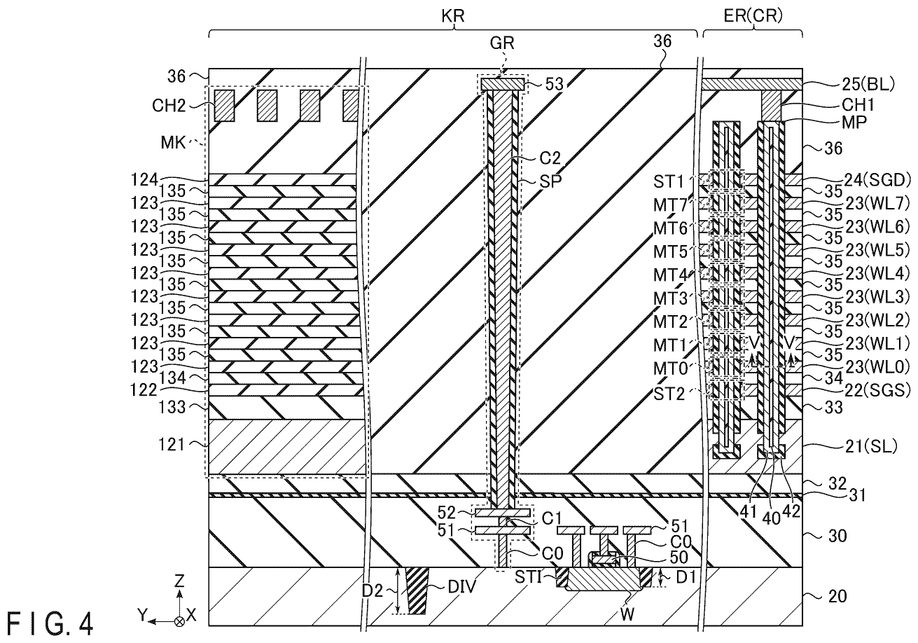

An example of the sectional structure of the semiconductor memory device 1 according to the embodiment will be described with reference to FIG. 4. FIG. 4 is a sectional view showing an example of the sectional structure of the semiconductor memory device according to the embodiment, which is taken along a line IV-IV in FIG. 3.

### 1.1.4.2.1 Element Region

With respect to the structure of the element region ER, the structure of the memory cell array 10 included in the core region CR will mainly be described below.

### (Memory Cell Array)

The sectional structure of the memory cell array 10 will be described.

The memory cell array 10 further includes conductor layers 21 to 25, insulator layers 30 to 36, a plurality of memory pillars MP, and a plurality of contacts CH1.

A semiconductor substrate 20 is, for example, a p-type semiconductor substrate. The insulator layer 30 is provided on the semiconductor substrate 20. Note that although not shown, in the element region ER, for example, circuits corresponding to the command register 11, the address register 12, the sequencer 13, the driver module 14, the row decoder module 15, the sense amplifier module 16, and the like are provided in the semiconductor substrate 20 and the insulator layer 30.

The insulator layer 31 is provided on the insulator layer 30. The insulator layer 31 contains, for example, silicon nitride. The insulator layer 31 functions as, for example, a barrier film for protecting a transistor provided on the semiconductor substrate 20 in a process of forming the stacked structure of the memory cell array 10.

The insulator layer 32 is provided on the insulator layer 31. The conductor layer 21 is provided on the insulator layer 32. The conductor layer 21 is, for example, provided in a plate shape spreading along the X-Y plane. The conductor layer 21 is used as the source line SL. The conductor layer 21 contains, for example, silicon doped with phosphorus.

The insulator layer 33 is provided on the conductor layer 21. The conductor layer 22 is provided on the insulator layer 33. The conductor layer 22 is, for example, provided in a plate shape spreading along the X-Y plane. The conductor layer 22 is used as the selection gate line SGS. The conductor layer 22 contains, for example, tungsten.

The insulator layer 34 is provided on the conductor layer 22. The eight conductor layers 23 and the eight insulator layers 35 are alternately stacked on the insulator layer 34. More specifically, the eight conductor layers 23 and the eight insulator layers 35 are stacked upward in the order of the conductor layer 23, the insulator layer 35, the conductor layer 23, . . . , the insulator layer 35, the conductor layer 23, and the insulator layer 35. The conductor layer 23 is, for example, provided in a plate shape spreading along the X-Y plane. The stacked eight conductor layers 23 are used upward as the word lines WL0 to WL7, respectively. Each conductor layer 23 contains, for example, tungsten.

The conductor layer 24 is provided on the uppermost insulator layer 35. The conductor layer 24 is, for example, provided in a plate shape spreading along the X-Y plane. The conductor layer 24 is used as the selection gate line SGD. The conductor layer 24 contains, for example, tungsten.

The insulator layer 36 is provided on the conductor layer 24. The plurality of conductor layers 25 are provided in the insulator layer 36. FIG. 4 shows only one conductor layer 25. Each conductor layer 25 is, for example, provided in a linear shape extending in the Y direction. Each conductor layer 25 is used as the bit line BL. The conductor layer 25 contains, for example, copper.

Each memory pillar MP is provided to extend in the Z direction. Each memory pillar MP extends through the conductor layers 22 to 24 and the insulator layers 33 to 35. The bottom portion of each memory pillar MP reaches the conductor layer 21. A portion where the memory pillar MP and the conductor layer 22 cross functions as the selection transistor ST2. A portion where the memory pillar MP and one conductor layer 23 cross functions as one memory cell transistor MT. A portion where the memory pillar MP and the conductor layer 24 cross functions as the selection transistor ST1. That is, each memory pillar MP functions as, for example, one NAND string NS. Note that FIG. 4 shows only two memory pillars MP included in one string unit SU among the plurality of memory pillars MP.

Each of the memory pillars MP includes, for example, a core member 40, a semiconductor layer 41, and a stacked film 42. The core member 40 is provided to extend in the Z direction. For example, the upper end of the core member 40 is included in a layer on the upper side of the conductor layer 24, and the lower end of the core member 40 is included in the conductor layer 21. The semiconductor layer 41 covers the periphery of the core member 40. A part of the semiconductor layer 41 contacts the conductor layer 21 via the side surface of the memory pillar MP. The stacked film 42 covers the side surface and the bottom surface of the semiconductor layer 41 except a portion where the semiconductor layer 41 and the conductor layer 21 are in contact with each other. The core member 40 contains, for example, an insulator such as silicon oxide. The semiconductor layer 41 contains, for example, silicon.

On the semiconductor layer 41 in each memory pillar MP, the columnar contact CH1 corresponding to the memory pillar MP is coupled. One conductor layer 25 corresponding to the contact CH1 is coupled on the contact CH1. That is, one bit line BL is coupled to each contact CH1. Note that FIG. 4 shows only the contact CH1 coupled to one of the two memory pillars MP included in the same string unit SU. The other of the two memory pillars MP is coupled to the conductor layer 25 (not shown) via the contact in a region (not shown).

### (Sectional Structure of Memory Pillar)

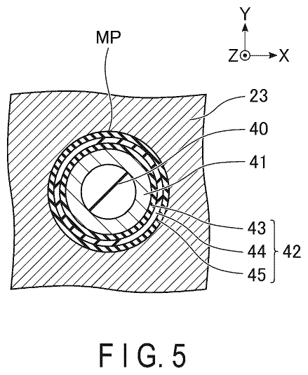

The sectional structure of the memory pillar MP will be described next with reference to FIG. 5. FIG. 5 is a sectional view showing an example of the sectional structure of the memory pillar of the memory cell array provided in the semiconductor memory device according to the embodiment, which is taken along a line V-V in FIG. 4. FIG. 5 is a view showing the sectional structure of the memory pillar MP including the conductor layer 23.

The stacked film 42 includes, for example, a tunnel insulating film 43, a charge accumulation film 44, and a block insulating film 45.

The core member 40 is provided at the center of the memory pillar MP. The semiconductor layer 41 surrounds the side surface of the core member 40. The tunnel insulating film 43 surrounds the side surface of the semiconductor layer 41. The charge accumulation film 44 surrounds the side surface of the tunnel insulating film 43. The block insulating film 45 surrounds the side surface of the charge accumulation film 44. The conductor layer 23 surrounds the side surface of the block insulating film 45. Each of the tunnel insulating film 43 and the block insulating film 45 contains, for example, silicon oxide. The charge accumulation film 44 contains, for example, an insulator capable of accumulating charges. The insulator is, for example, silicon nitride.

The semiconductor layer 41 functions as the current paths of the memory cell transistors MT0 to MT7 and the selection transistors ST1 and ST2.

### 1.1.4.2.2 Kerf Region

Referring back to FIG. 4, the sectional structure of the kerf region KR will be described.

### (Guard Ring)

The structure of the guard ring GR will be described first.

The guard ring GR includes, for example, contacts C0, C1, and C2, conductor layers 51, 52, and 53, and a spacer SP.

In the guard ring GR, the contact C0 is coupled on the semiconductor substrate 20. The conductor layer 51 is provided on the contact C0. The contact C1 is provided on the conductor layer 51. The conductor layer 52 is provided on the contact C1. The contacts C0 and C1 and the conductor layers 51 and 52 are provided in the insulator layer 30.

Note that FIG. 4 shows only one combination of the contacts C0 and C1 and the conductor layers 51 and 52 but the present invention is not limited to this. The guard ring GR may include, for example, a plurality of combinations. That is, the guard ring GR can contact the semiconductor substrate 20 via a plurality of locations.

The contact C2 is provided on the conductor layer 52. The contact C2 is provided to extend in the Z direction. The contact C2 is, for example, provided in a wall shape surrounding the element region ER. For example, the contact C2 extends through the insulator layers 31 and 32. This locates the upper surface of the contact C2 in, for example, the insulator layer 36.

The spacer SP is provided to surround the side surface of the contact C2. The spacer SP contains an insulator.

The conductor layer 53 is provided on the upper surface of the contact C2. The conductor layer 53 may be coupled to, for example, a conductor portion exposed to the upper surface of the semiconductor memory device 1 (not shown). This causes the guard ring GR to function as, for example, a discharge portion for stabilizing the potential of the component in the semiconductor substrate 20.

In the kerf region KR, for example, a circuit different from the memory cell array 10, the command register 11, the address register 12, the sequencer 13, the driver module 14, the row decoder module 15, the sense amplifier module 16, and the like is provided on the periphery of the guard ring GR in the semiconductor substrate 20 and the insulator layer 30. The circuit is, for example, a characteristic check circuit or the like.

In the circuit, a well region W is provided in the upper portion of the semiconductor substrate 20. Although not shown, the well region is provided with a source and a drain at a predetermined interval. A gate electrode 50 is provided, via a gate insulating film, on the semiconductor substrate 20 between the source and the drain. With this configuration, a MOSFET structure can be provided on the semiconductor substrate 20. Note that FIG. 4 shows only one MOSFET structure but the components shown in FIG. 4 are merely examples, and the circuit can include other components.

On the periphery of the well region W, for example, a member STI is provided in the upper portion of the semiconductor substrate 20 to surround the well region W. The member STI is a structure for preventing interference between the MOSFET and other components. That is, the member STI is an element isolation structure. The upper surface of the member STI is located at the same height as that of the upper surface of the semiconductor substrate 20. Furthermore, a depth from the upper surface of the semiconductor substrate 20 to the lower surface of the member STI is represented by a depth D1. The contacts C0 are provided on the upper

surfaces of the gate electrode 50, source, and drain. The conductor layer 51 is provided on each contact C0.

### (Alignment Mark)

The structure of the alignment mark MK will be described next.

The alignment mark MK is, for example, provided on the insulator layer 32. The alignment mark MK includes a conductor layer 121, stacked members 122 to 124, insulator layers 133 to 135, and contacts CH2.

The conductor layer 121 is provided on the insulator layer 32. The conductor layer 121 is, for example, provided in a plate shape spreading along the X-Y plane. The conductor layer 121 is provided by, for example, a process of forming the conductor layer 21. This provides the conductor layer 121 in the same layer as the conductor layer 21. In addition, the conductor layer 121 contains, for example, the same material as that of the conductor layer 21.

The insulator layer 133 is provided on the conductor layer 121. The insulator layer 133 is provided by, for example, a process of forming the insulator layer 33. This provides the insulator layer 133 in the same layer as the insulator layer 33. The stacked member 122 is provided on the insulator layer 133. The stacked member 122 is, for example, provided in a plate shape spreading along the X-Y plane. The stacked member 122 is provided by, for example, a process of forming the conductor layer 22. This provides the stacked member 122 in the same layer as the conductor layer 22. Furthermore, the stacked member 122 contains, for example, a sacrificial material for forming the conductor layer 22. The sacrificial material is, for example, an insulator. Furthermore, the stacked member 122 may contain the same material as that of the conductor layer 22.

The insulator layer 134 is provided on the stacked member 122. The insulator layer 134 is provided by, for example, a process of forming the insulator layer 34. This provides the insulator layer 134 in the same layer as the insulator layer 34. The eight stacked members 123 and the eight insulator layers 135 are alternately stacked on the insulator layer 134. More specifically, the eight stacked members 123 and the eight insulator layers 135 are stacked upward in the order of the stacked member 123, the insulator layer 135, the stacked member 123, . . . , the insulator layer 135, the stacked member 123, and the insulator layer 135. The stacked member 123 is, for example, provided in a plate shape spreading along the X-Y plane. The stacked member 123 is provided by, for example, a process of forming the conductor layer 23. In addition, the insulator layer 135 is provided by, for example, a process of forming the insulator layer 35. This provides each of the eight stacked members 123 in the same layer as each of the eight conductor layers 23. Each of the eight insulator layers 135 is provided in the same layer as each of the eight insulator layers 35. The stacked member 123 contains, for example, a sacrificial material for forming the conductor layer 23. Furthermore, the stacked member 123 may contain the same material as that of the conductor layer 23.

The stacked member 124 is provided on the uppermost insulator layer 135. The stacked member 124 is, for example, provided in a plate shape spreading along the X-Y plane. The stacked member 124 is provided in the same layer as the conductor layer 24. The stacked member 124 is provided by, for example, a process of forming the conductor layer 24. This provides the stacked member 124 in the same layer as the conductor layer 24. The stacked member 124 contains, for example, a sacrificial material for forming the conductor layer 24. Furthermore, the stacked member 124 may contain the same material as that of the conductor layer 24.

The plurality of columnar contacts CH2 are provided in the insulator layer 36 above the stacked member 124. The contacts CH2 are provided by, for example, the same process as that of the contacts CH1. This provides, for example, the contacts CH2 in the same layer as the contacts CH1. The contacts CH2 are provided in the upper portion of the alignment mark MK. Thus, the alignment mark MK can be used for alignment in manufacturing of the semiconductor memory device 1.

### (Member DIV)

The structure of the member DIV will be described next.

The member DIV is provided in, for example, the same layer as the semiconductor substrate 20. The member DIV is made of a material containing an insulator. The member DIV is made of, for example, a material whose stress generated when the member DIV is buried in the semiconductor substrate 20 is lower than a stress generated when the member STI is buried in the semiconductor substrate 20. The member DIV is provided by, for example, burying the above material in a trench (groove) formed by etching the semiconductor substrate 20. The upper surface of the member DIV is located, for example, at the same height as that of the upper surface of the semiconductor substrate 20. A depth from the upper surface of the semiconductor substrate 20 to the lower surface of the member DIV is represented by a depth D2. The depth D2 is larger than the depth D1 (D2>D1). In other words, the lower surface of the member DIV is located below the lower surface of the member STI.

Note that FIG. 4 does not illustrate a circuit provided in the semiconductor substrate 20 and the insulator layer 30 in the element region ER but the circuit includes, for example, the same structure as the MOSFET structure in the kerf region KR shown in FIG. 4. That is, in the element region ER as well, the same element isolation structure as the member STI is provided.

### 1.2 Effect According to Embodiment

According to the embodiment, it is possible to

improve the yield of the semiconductor memory device 1. The effect of the embodiment will be described below.

The semiconductor memory device 1 according to the embodiment includes the semiconductor substrate 20, the plurality of conductor layers 23, the memory pillars MP each extending through the plurality of conductor layers 23, the plurality of stacked members 123, and the members STI and DIV. The semiconductor memory device 1 can be divided into the element region ER and the kerf region KR that surrounds the outside of the element region when viewed from above. The plurality of conductor layers 23 and the memory pillars MP are provided above the semiconductor substrate 20 in the element region ER. The plurality of stacked members 123 are provided above the semiconductor substrate 20 in the kerf region KR. The plurality of stacked members 123 are included in the alignment mark MK. Furthermore, the semiconductor substrate 20 is provided with the well region W. The well region W is isolated, by the member STI, from other components provided in the semiconductor substrate 20. The member DIV is aligned with the plurality of stacked members 123 in the X direction or the Y direction, and is provided between the plurality of stacked members 123 and the element region ER. The lower surface of the member DIV is located below the lower surface of the member STI. With the above configuration, the semiconductor memory device 1 according to the embodiment can suppress a crystal defect and dislocation in the semiconductor substrate 20 generated in the kerf region KR from extending into the element region ER of the semiconductor substrate 20. It is thus possible to suppress occurrence of a device defect. Therefore, it is possible to improve the yield of the semiconductor memory device 1.

Supplementarily explaining, for example, when a stress caused by the alignment mark propagates beyond the element isolation structure provided in the kerf region in the semiconductor substrate, a crystal defect and dislocation generated in the kerf region may extend into the element region. In this case, a device defect may occur due to the crystal defect and dislocation. According to the embodiment, as described above, by including the member DIV having the lower surface located below the lower surface of the member STI, it is possible to reduce the influence of the stress between the alignment mark MK and the element region ER. This can suppress the influence of the stress by the alignment mark MK from reaching the element region.

### 2 Modifications

Note that various modifications can be made to the above-described embodiment.

A semiconductor memory device according to each modification will be described below.

### 2.1 First Modification

The above-described embodiment has explained the example in which the member DIV is provided between the element region ER and the alignment mark MK corresponding to the member DIV when viewed from above. However, the present invention is not limited to this. The member DIV may be provided to surround the alignment mark MK corresponding the member DIV when viewed from above. With respect to the configuration of the semiconductor memory device 1 according to the first modification, points different from the configuration of the semiconductor memory device according to the embodiment will mainly be described below.

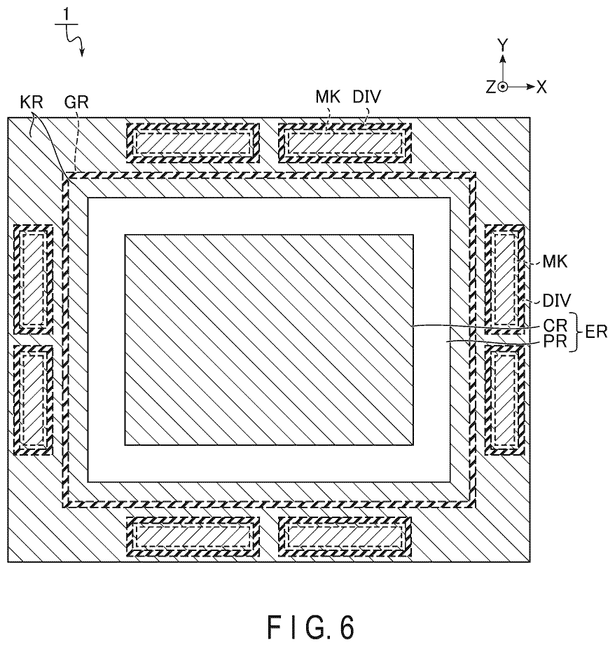

The planar layout of the semiconductor memory device 1 according to the first modification will be described with reference to FIG. 6. FIG. 6 is a plan view showing an example of the planar layout of the semiconductor memory device according to the first modification.

The semiconductor memory device 1 according to the first modification is divided into the element region ER and the kerf region KR, similar to the semiconductor memory device according to the embodiment. The configuration of the element region ER and the plurality of alignment marks MK and the guard ring GR in the kerf region KR is the same as that according to the embodiment. The member DIV will be described below.

As described above, the member DIV is provided to surround the alignment mark MK corresponding to the member DIV when viewed from above. That is, the member DIV is provided to form the sides of a rectangle surrounding the rectangular alignment mark MK when viewed from above.

Note that the sectional structure of the semiconductor memory device 1 according to the first modification can be the same as in the embodiment except that the member DIV is provided to surround the alignment mark MK.

According to the first modification as well, it is possible to obtain the same effect as in the embodiment.

According to the first modification, when the member DIV is provided to surround the alignment mark MK, it is possible to suppress extension of a crystal defect and dislocation from the kerf region KR to the outside of the semiconductor memory device 1 in addition to extension of a crystal defect and dislocation from the kerf region KR of the semiconductor memory device 1 to the element region ER. This can suppress extension of a crystal defect and dislocation to adjacent chips among a plurality of chips (semiconductor memory devices 1) formed on a wafer in a manufacturing process in addition to extension of a crystal defect and dislocation to the element region ER of the self-device. Therefore, it is also possible to suppress occurrence of device defects of the adjacent chips.

### 2.2 Second Modification

Each of the above-described embodiment and first modification has explained the example in which the upper surface of the member DIV is located at the same height as that of the upper surface of the semiconductor substrate 20. However, the present invention is not limited to this. The upper surface of the member DIV may be provided above the upper surface of the semiconductor substrate 20. With respect to the configuration of the semiconductor memory device 1 according to the second modification, points different from the configuration of the semiconductor memory device according to each of the embodiment and the first modification will mainly be described below.

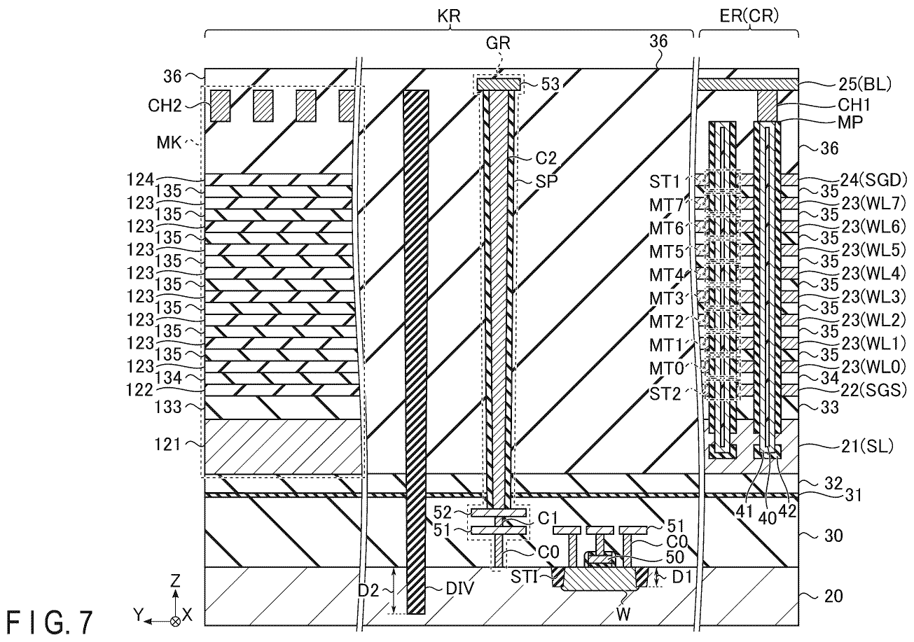

The planar layout of the semiconductor memory device 1 according to the second modification can be the same as that of the semiconductor memory device according to each of the embodiment and the first modification. The sectional structure of the semiconductor memory device 1 according to the second modification will be described below with reference to FIG. 7. FIG. 7 is a sectional view showing an example of the sectional structure of the semiconductor memory device according to the second modification.

In the sectional structure of the semiconductor memory device 1, the structure of the element region ER is the same as that of the element region according to the embodiment. The structure of the alignment marks MK, the circuits provided in the semiconductor substrate 20 and the insulator layer 30, the member STI, and the guard ring GR in the kerf region KR is the same as that according to the embodiment.

The upper surface of the member DIV according to the second modification is located above the upper surface of the semiconductor substrate 20. The height of the upper surface of the member DIV may reach the height equal to that of the upper end of the alignment mark MK. For example, the member DIV is provided by burying a material containing an insulator in a trench formed by etching a stacked body formed in a manufacturing process.

According to the second modification as well, it is possible to obtain the same effect as in the embodiment.

### 2.3 Third Modification

Each of the above-described embodiment, first modification, and second modification has explained the example in which the influence of a stress is reduced by including the member DIV. However, the present invention is not limited to this. In addition to the member DIV, a defect fixing portion that traps a crystal defect may be included. With respect to the configuration of the semiconductor memory device 1 according to the third modification, points different from the configuration of the semiconductor memory device according to each of the embodiment, the first modification, and second modification will mainly be described below.

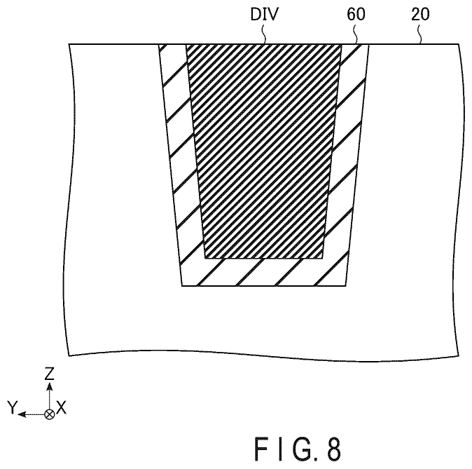

The planar layout of the semiconductor memory device 1 according to the third modification can be the same as that of the semiconductor memory device according to each of the embodiment, the first modification, and the second modification. The sectional structure of the semiconductor memory device 1 according to the third modification can be the same as that of the semiconductor memory device according to each of the embodiment, the first modification, and the second modification except that the defect fixing portion is included. The defect fixing portion will be described below with reference to FIG. 8. FIG. 8 is a sectional view showing an example of the defect fixing portion provided in the semiconductor memory device according to the third modification. FIG. 8 is an enlarged view of a portion corresponding to the member in the sectional view corresponding to FIG. 4 of the embodiment.

As shown in FIG. 8, the semiconductor memory device 1 further includes a defect fixing portion 60.

The defect fixing portion 60 is, for example, provided to cover at least portions of the lower surface and the side surface of the member DIV. The defect fixing portion 60 contains, for example, at least one of elements having an effect of trapping a crystal defect. The elements are, for example, carbon, oxygen, and boron. The defect fixing portion 60 is, for example, provided by ion implantation of the element in the semiconductor substrate 20. Alternatively, the defect fixing portion 60 may be provided by depositing a material having a crystal structure different from that of the semiconductor substrate 20. The material is, for example, polysilicon, silicon oxide, silicon nitride, or silicon carbide.

According to the third modification as well, it is possible to obtain the same effect as in the embodiment.

According to the third modification, by including the defect fixing portion 60, it is possible to trap a crystal defect between the alignment mark MK and the element region ER. This can effectively suppress extension of dislocation. With this configuration as well, it is possible to improve the yield of the semiconductor memory device 1.

### 3. Other Embodiments

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a substrate including a first region and a second region surrounding an outside of the first region when viewed from above;
a first member configured to separate, in a direction parallel to the substrate, a well region provided in the substrate and a region of the substrate provided to surround the well region when viewed from above;
a plurality of conductor layers provided above the first region and arranged apart from each other in a first direction perpendicular to the substrate;
a memory pillar provided above the first region and extending through the plurality of conductor layers, whose portions crossing the plurality of conductor layers each function as a memory cell;
a plurality of stacked members provided above the second region and arranged apart from each other in the first direction; and
a second member provided between the plurality of stacked members and the first region in a second direction crossing the first direction,
wherein a lower surface of the second member is located below a lower surface of the first member.

2. The device according to claim 1, further comprising a guard ring provided in a wall shape in the second region and coupled to the substrate,
wherein the second member is provided outside the guard ring when viewed from above.

3. The device according to claim 1 further comprising a defect fixing portion configured to cover at least portions of the lower surface and a side surface of the second member.

4. The device according to claim 1, wherein the second member has a lower stress than the substrate.

5. The device according to claim 1, wherein the second member is an insulator.

6. The device according to claim 1, wherein the second member is provided in the same layer as the substrate.

7. The device according to claim 1, wherein an upper surface of the second member is located above an upper surface of the substrate.

8. The device according to claim 1, wherein each of the plurality of stacked members is included in the same layer as each of the plurality of conductor layers.

9. The device according to claim 1, wherein the plurality of stacked members are insulators.

10. The device according to claim 1, wherein the plurality of stacked members are conductors.

11. The device according to claim 1, wherein the plurality of stacked members are components included in an alignment mark.

12. A semiconductor memory device comprising:
a substrate including a first region and a second region surrounding an outside of the first region when viewed from above;
a plurality of conductor layers provided above the first region and arranged apart from each other in a first direction perpendicular to the substrate;
a memory pillar provided above the first region and extending through the plurality of conductor layers, whose portions crossing the plurality of conductor layers each function as a memory cell;
a plurality of stacked members provided above the second region and arranged apart from each other in the first direction; and
a second member provided to surround the plurality of stacked members when viewed from above, whose lower surface is provided below an upper surface of the substrate.

13. The device according to claim 12, further comprising a first member configured to separate a well region provided in the substrate from another region of the substrate,
wherein the lower surface of the second member is located below a lower surface of the first member.
